(19) United States
(12) Patent Application Publication
(10) Pub. No.: US 2008/0211099 A1
(43) Pub. Date: Sep. 4, 2008

(54) SEMICONDUCTOR DEVICE

(75) Inventor: Yoshihisa MATSUBARA, Kanagawa (JP)

Correspondence Address: Young & Thompson, Suite 500, 209 Madison Street, Alexandria, VA, 22314, US

(73) Assignee: NEC ELECTRONICS CORPORATION, Kawasaki (JP)

(21) Appl. No.: 12/040,937

(22) Filed: Mar. 3, 2008

(30) Foreign Application Priority Data
Mar. 2, 2007 (JP) 2007-52330

(51) Int. Cl. H01L 23/48

(52) U.S. Cl. 257/751; 257/E23.01

(57) ABSTRACT

A semiconductor device (1) includes an insulating film (18) which is formed on an interlayer insulating film (10) and includes a low-permittivity film (14), and two wirings (24) formed in wiring grooves (26) formed in the insulating film (18). The two wirings have a length of “L”. The insulting film (18a) in a portion sandwiched between the two wirings (24) and contacting the two wirings (24) has a height of “H”, the length of “L” and a width of “W”. The insulating film (18a) has side wall surfaces contacting the wirings (24), and an aspect ratio Y of the insulating film (18a) and an area X [nm²] of the side wall surfaces of the insulating film (18a) are set so that a relation of “Y≦−2.9×10⁻⁷·X+9.49” is satisfied.

### BACKGROUND OF THE INVENTION

1. Field of the Invention

The present invention relates to a semiconductor device and, in particular, relates to a semiconductor device having damascene structure wirings.

2. Description of Related Art

In recent years, it has become mainstream to, in a wiring structure used in a semiconductor integrated circuit, reduce a resistance of a wiring material and lower a permittivity of an insulating film for inter-wiring dielectric isolation in order to minimize a wiring delay.

Also, from the viewpoint of wiring reliability, it is required that the wiring structure has a high tolerance to electro-migration and stress migration.

Further, from the viewpoint of designing of wiring dimensions, wiring film thicknesses are generally set so that a wiring in a lower layer close to a silicon substrate becomes thin and a wiring in an upper layer apart from the silicon substrate becomes thick. The wiring film thicknesses are generally determined by IR drop, reliability, and process fine workability of a power supply wiring or the like. Also, the wiring film thickness of the local wiring in the lower layer is generally determined by a selection ratio between a resist film and an insulating film worked and a patterning characteristic of photolithography.

In JP 2001-68554 A, a technique, in which a range of a length L of wirings is defined by a value of a ratio W/H between a width W of the wirings and a thickness H of an insulating film immediately below the wirings for the purpose of providing an LSI designing method of making it possible to suppress fluctuations of a wiring capacitance C or a wiring delay RC suited for practical use while giving consideration to process variations, is described.

Also, in JP 2004-55919 A, a technique, in which when a wiring width or a volume of unit wirings exceeds a predetermined value, the number of the via contacts is increased for purpose of improving a stress migration tolerance resulting from via contacts, is described.

As a result of an earnest study, however, the present inventor has found that when it is desired to improve reliability of wirings, it is insufficient to merely define a length of the wirings or the number of via contacts formed for the wirings.

More specifically, when a porous film is used as an insulating film for inter-wiring dielectric isolation in order to lower a permittivity of the insulating film, when an aspect ratio of the insulating film for the wiring dielectric isolation increases at a location with the minimum wiring gap, there occurs a wiring failure (an increase in a wiring resistance or a decrease in inter-wiring dielectric voltage).

It has been found that, as a result of an earnest search by the present inventor, when wiring grooves are formed in an insulating film that is a porous film in a damascene process that is a wiring forming process, at a location at which a wiring failure occurs, as shown in FIG. 18A on an interlayer insulating film 102, toppling over of the insulating film 104 that is a porous film occurs and a location at which a width of the wiring grooves 106 is locally narrowed is generated. Note that FIG. 18A is a cross-sectional view after the wiring groove formation in the damascene process.

In addition, as a result of a search for a cause of insulating film toppling over at the time of wiring groove formation, it has been found that at an etching apparatus that performs selective etching of an insulating film, when a partition between a process chamber and a transport chamber is opened, due to a flow of a gas caused by a pressure difference between the process chamber and the transport chamber, the insulating film of a fine pattern is toppled over.

In general, in an etching apparatus with vacuum exhaustion, a pressure difference is set between a transport chamber and a process chamber. In other words, a pressure in the process chamber is set lower than a pressure in the transport chamber. Here, when an etching gas (CHF3 gas, for instance) or the like in the process chamber flows into the transport chamber, there arises a problem that the transport chamber is corroded, so the pressure difference is necessarily set between the process chamber and the transport chamber. Note that it is general that the pressure difference between the transport chamber and the process chamber is set to around 1×10−2 Torr.

At the location of FIG. 18A at which the width of the wiring grooves 106 is locally narrowed, as shown in FIG. 18B, an embedding property of a metal 108 that is to be wirings is deteriorated and voids 110 resulting from an embedding failure occur. Note that FIG. 18B is a cross-sectional view after the metal that is to be wirings is embedded into the wiring grooves in the damascene process.

By removing an unnecessary portion of the metal from a state in FIG. 18B through CMP or the like, as shown in FIG. 18C, wirings 112 are formed. A horizontal cross-sectional view of FIG. 18C taken along line A-A is shown in FIG. 19. It is considered that as shown in FIG. 19, at the location at which the insulating film 104 that is a porous film topples over, a width of the wirings 112 is narrowed and the voids 110 occur in the wirings 112, so a resistance of the wirings 112 is locally increased.

Also, as shown in a top view in FIG. 20, at the location at which the insulating film 104 that is a porous film topples over, a phenomenon, in which a width of the insulating film 104 that is a porous film is narrowed, is also observed and it is considered that at a location 114 at which the width of the insulting film 104 that is a porous film is narrowed, an inter-wiring dielectric voltage is lowered.

It should be noted here that it is considered that the reason why the insulating film toppling over tends to occur in the case of the insulating film 104 that is a porous film is that the insulating film that is a porous film is low in mechanical strength as an insulating film.

### SUMMARY

According to one aspect of the present invention, there is provided a semiconductor device, including:

a semiconductor substrate;

a first wiring provided over the semiconductor substrate and extending in a first direction;

a second wiring provided over the semiconductor substrate, and extending in the first direction; and

an insulating film provided between the first wiring and the second wiring,

in which an aspect ratio Y of the insulating film defined by a value obtained by dividing a height H of the insulating film by a width W of the insulating film along a direction vertical to the first direction and a side wall area X [nm²] of the insulating film in a portion contacting the first wiring and the second wiring have the following relation:

Y≦−2.9×10⁻⁷·X+9.49.

According to the semiconductor device of the present invention, by limiting the side wall area X of the insulating film in the portion interposed between the two wirings and contacting the two wirings in accordance with the aspect ratio Y of the insulating film in the portion so that the aspect ratio Y of the insulating film and the side wall area X of the insulating film are in a predetermined relation, it becomes possible to prevent insulating film from toppling over, thereby making it possible to prevent an increase in wiring resistance and a decrease in inter-wiring dielectric voltage resulting from the insulating film toppling over.

It should be noted here that, the construction in which, in accordance with the aspect ratio Y of the insulating film, not a length of the insulting film but the side wall area X of the insulating film is limited, is based on a finding by the present inventor that even with the same length of the insulating film, as the side wall area increases, the insulating film toppling over tends to occur.

Further, according to another aspect of the present invention, there is provided a semiconductor device, including:

a first wiring and a second wiring running in parallel to each other with a predetermined gap therebetween; and

an insulating film interposed between the first wiring and the second wiring,

in which when the predetermined gap is referred to as “W [nm]”, a height of the first wiring are referred to as “H [nm]”, and a length of a portion of the first wiring facing the second wiring, is referred to as “L [nm]”, the following relation is satisfied:

W/H≦−2.9×10⁻⁷×(L×H)+9.49.

According to the present invention, it becomes possible to prevent an increase in wiring resistance and a decrease in inter-wiring dielectric voltage resulting from insulating film toppling over.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B each show a semiconductor device according to an embodiment of the present invention;

FIG. 2 is a perspective view in which only a portion of an insulating film is extracted from FIG. 1;

FIG. 3 shows a relation between a critical aspect ratio of the insulating film and a side wall area of the insulating film;

FIG. 4 is a process cross-sectional view of a method of manufacturing the semiconductor device according to the embodiment of the present invention;

FIG. 5 is another process cross-sectional view of the method of manufacturing the semiconductor device according to the embodiment of the present invention;

FIG. 6 is still another process cross-sectional view of the method of manufacturing the semiconductor device according to the embodiment of the present invention;

FIG. 7 is a further process cross-sectional view of the method of manufacturing the semiconductor device according to the embodiment of the present invention;

FIG. 8 is a further process cross-sectional view of the method of manufacturing the semiconductor device according to the embodiment of the present invention;

FIG. 9 is a further process cross-sectional view of the method of manufacturing the semiconductor device according to the embodiment of the present invention;

FIG. 10 is a further process cross-sectional view of the method of manufacturing the semiconductor device according to the embodiment of the present invention;

FIG. 11 is a further process cross-sectional view of the method of manufacturing the semiconductor device according to the embodiment of the present invention;

FIG. 12 shows a modification of the semiconductor device according to the embodiment of the present invention;

FIG. 13 also shows the modification of the semiconductor device according to the embodiment of the present invention;

FIG. 14 shows the modification of the semiconductor device according to the embodiment of the present invention;

FIG. 15 shows an example in which in the same wiring layer of the semiconductor device according to the present invention, wirings provided parallel to each other with the minimum wiring gap in-between and wirings provided parallel to each other with a wiring gap wider than the minimum wiring gap in-between are arranged;

FIGS. 16A and 16B each show connections among multiple wirings whose wiring lengths are limited;

FIGS. 17A and 17B each show other connections among multiple wirings whose wiring lengths are limited;

FIGS. 18A to 18C are each an explanatory diagram of a problem solved by the present invention;

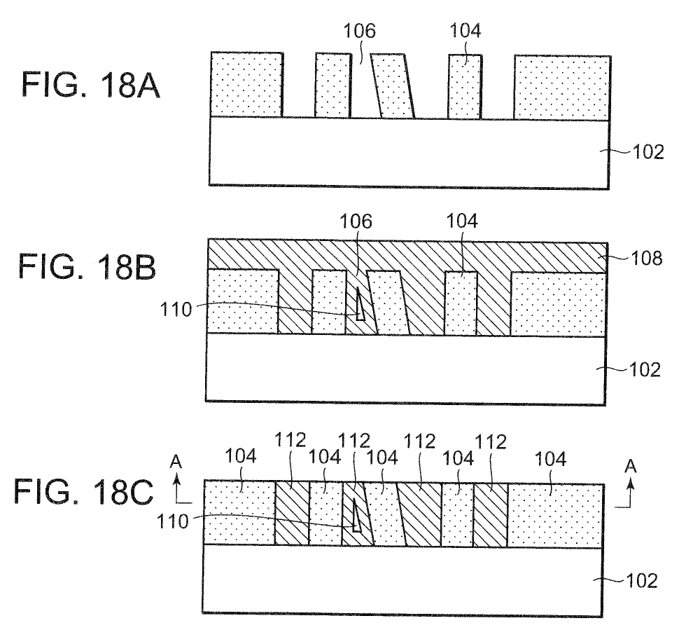

FIG. 19 is another explanatory diagram of the problem solved by the present invention; and

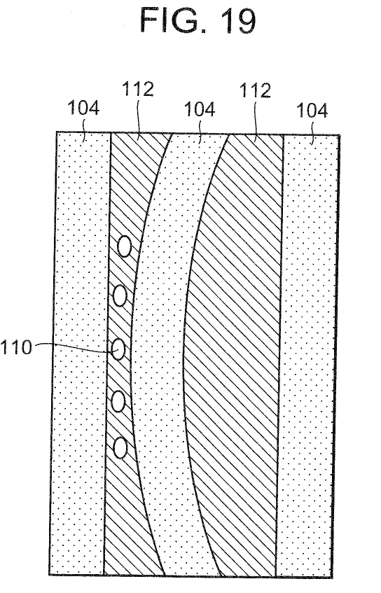

FIG. 20 is still another explanatory diagram of the problem solved by the present invention.

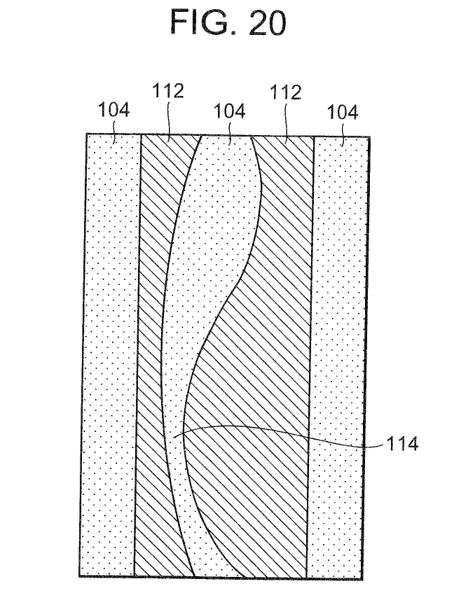

### DETAILED DESCRIPTION OF THE PREFERRED EMBODIMENTS

Hereinafter, a semiconductor device according to an embodiment of the present invention will be described with reference to the drawings.

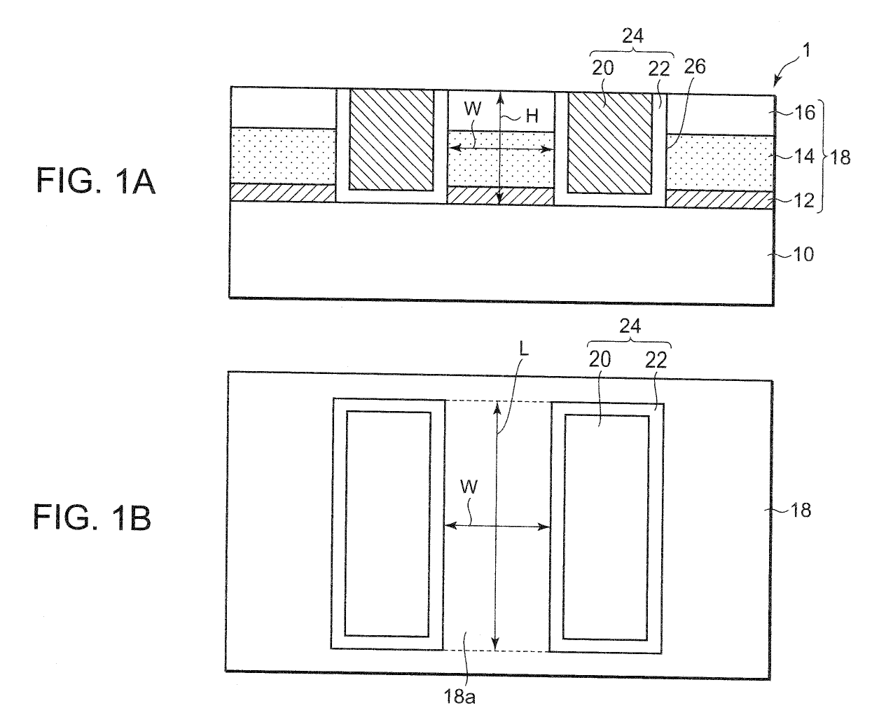

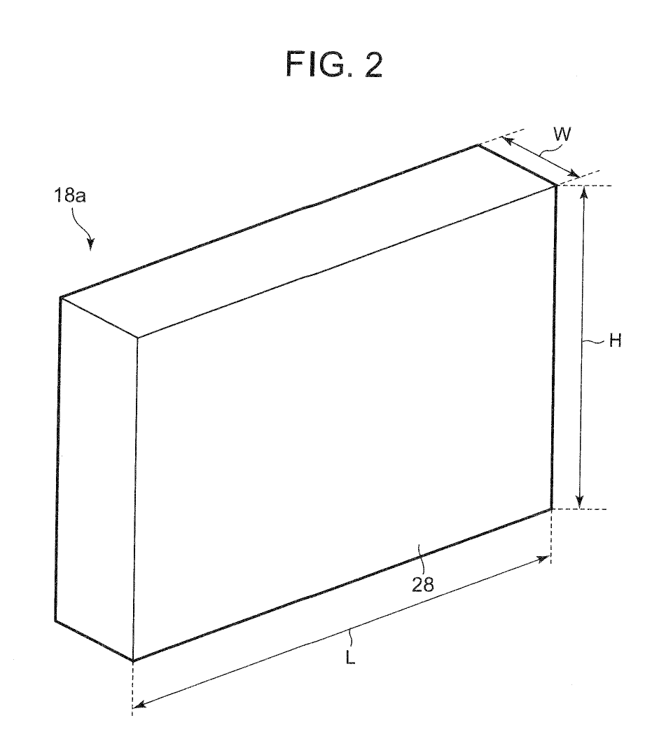

FIGS. 1A, 1B, and 2 are each an explanatory diagram of the semiconductor device of this embodiment.

FIG. 1A is a cross-sectional view of the semiconductor device of this embodiment. In FIG. 1A, the semiconductor device 1 includes an interlayer insulating film 10 formed over a semiconductor substrate (not shown), an insulating film 18 formed on the interlayer insulating film 10, and wirings 24 formed in wiring grooves 26 formed in the insulating film 18.

The insulating film 18 includes an etching stopper film 12, a low-permittivity film 14 formed on the etching stopper film 12, and a cap film 16 formed on the low-permittivity film 14.

Also, the wirings 24 each include a copper wiring 20 and a barrier metal 22 formed on side surfaces and a bottom surface of the copper wiring 20. Further, the insulating film 18 sandwiched between the two wirings 24 has a width W, a height H, and an aspect ratio Y (=H/W) defined by a value obtained by dividing the height H by the width W.

FIG. 1B is a top view of FIG. 1A. As shown in FIG. 1B, the two wirings 24 each have a length L and the insulating film 18a in a portion sandwiched between the two wirings 24 and contacting the two wirings 24 has a length L and the width W.

FIG. 2 is a perspective view in which only the insulating film 18a is extracted. As shown in FIG. 2, the insulating film 18a has the length L, the width W, and the height H and includes side wall surfaces 28 contacting the wirings 24, with an area X of the side wall surfaces 28 being defined by a value obtained by multiplying the height H by the length L.

In the semiconductor device in this embodiment, in order to prevent insulating film toppling over that is a cause of an increase in wiring resistance and a decrease in inter-wiring dielectric voltage, the aspect ratio Y of the insulating film 18a and the area X [nm²] of the side wall surfaces 28 of the insulating film 18a are set so that a relation of “Y≦−2.9×10⁻⁷·X+9.49” is satisfied.

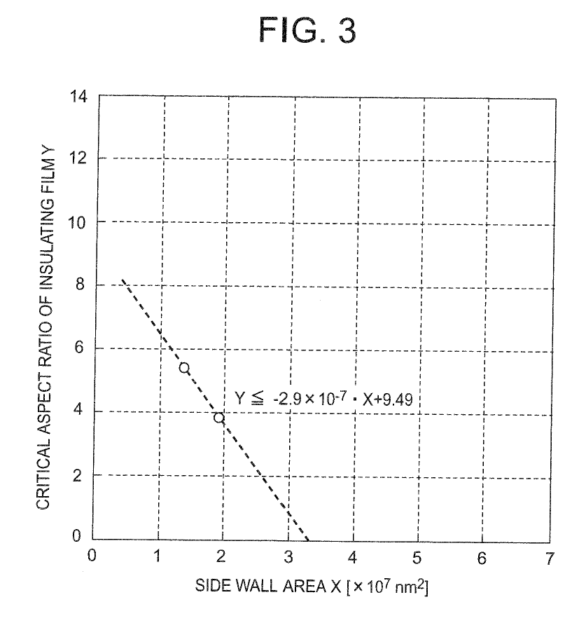

In order to derive the relational expression described above, the present inventor has searched for a critical aspect ratio Y of the insulating film with respect to the area X [nm²] of the side wall surfaces 28 of the insulating film at which the insulating film toppling over does not occur. A result of the search is shown in a graph of FIG. 3.

In the graph of FIG. 3, the vertical axis represents the critical aspect ratio Y of the insulating film and the horizontal axis indicates the side wall area X [nm²] of the insulating film, with the critical aspect ratio Y of the insulating film with respect to each area X [nm²] of the side wall surfaces of the insulating film being plotted. Here, “the critical aspect ratio of the insulating film” means that, with respect to the area X [nm²] of the side wall surfaces of the insulating film, the insulating film toppling over occurs at an aspect ratio Y exceeding the critical aspect ratio and the insulating film toppling over does not occur at an aspect ratio Y equal to or smaller than the critical aspect ratio. Note that it has been confirmed that when the area X of the side wall surfaces of the insulating film exceeds 4×10⁻⁷ [nm²], the insulating film toppling over occurs at any aspect ratio. It can be understood from the graph of FIG. 3 that when the aspect ratio Y of the insulating film and the side wall area X [nm²] of the insulating film satisfy the relation of “Y≦−2.9×10⁻⁷·X+9.49”, it becomes possible to suppress the insulating film toppling over.

Next, a method of manufacturing the semiconductor device of this embodiment will be described with reference to the drawings.

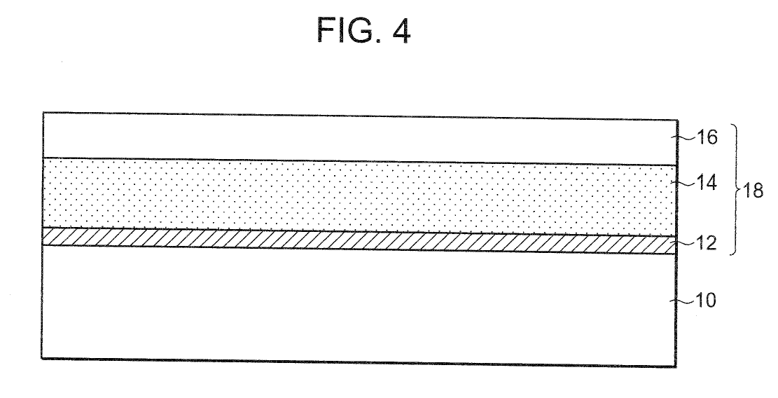

FIGS. 4 to 11 are each a process cross-sectional view for explanation of the method of manufacturing the semiconductor device of this embodiment.

First, as shown in FIG. 4, the interlayer insulating film 10 is formed over the semiconductor substrate (not shown). The interlayer insulating film is, for instance, an SiO2 film and has a film thickness of 500 nm. Then, the insulating film 18 is formed on the interlayer insulating film 10. The insulating film 18 includes the cap film 16, the low-permittivity film 14, and the etching stopper film 12 in the stated order from the top. The cap film 16 is, for instance, an SiO2 film and has a film thickness of around 100 nm. The low-permittivity film 14 is, for instance, “Aurora (trademark, manufactured by ASM Japan K.K.)” that is a porous film, whose permittivity is around 2.5, and has a film thickness of around 150 nm. The etching stopper film 12 is, for instance, an SiCN film and has a film thickness of around 25 nm.

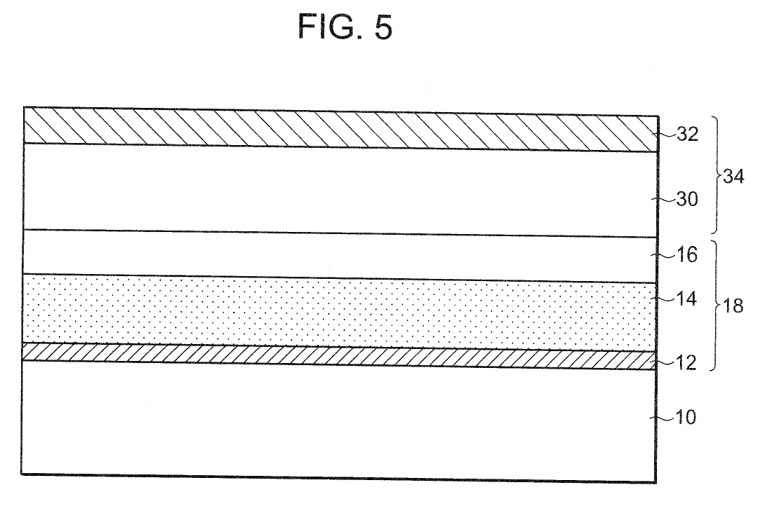

Next, as shown in FIG. 5, a multilayer resist film 34 including a lower-layer resist film 30 and an upper-layer resist film 32 is applied on the insulating film 18. The lower-layer resist film 30 is, for instance, “NFC-US864 (trademark)” and has a film thickness of around 300 nm. The upper-layer resist film 32 is, for instance, “F-SSQ (trademark)” and has a film thickness of around 90 nm.

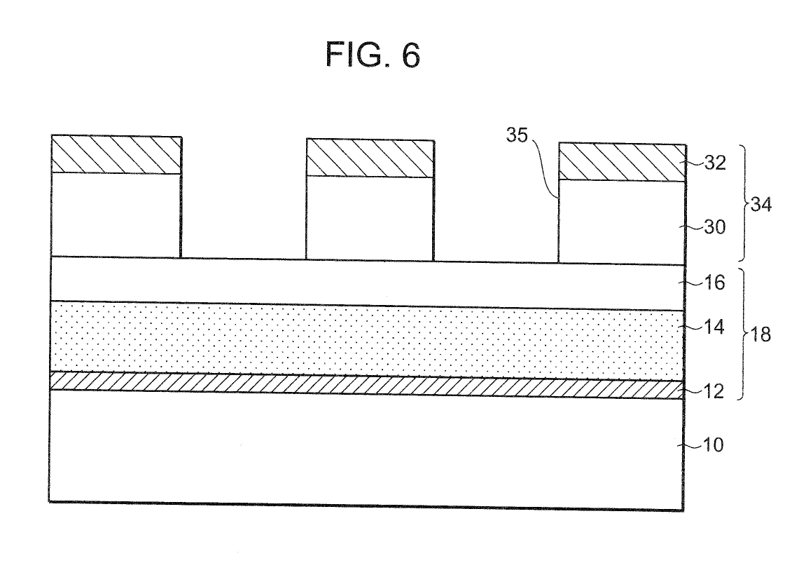

Then, as shown in FIG. 6, patterning of the multilayer resist film 34 is performed with a predetermined lithography technique. Note that opening portions 35 of the multilayer resist film 34 formed through the patterning correspond to the wiring grooves to be formed later.

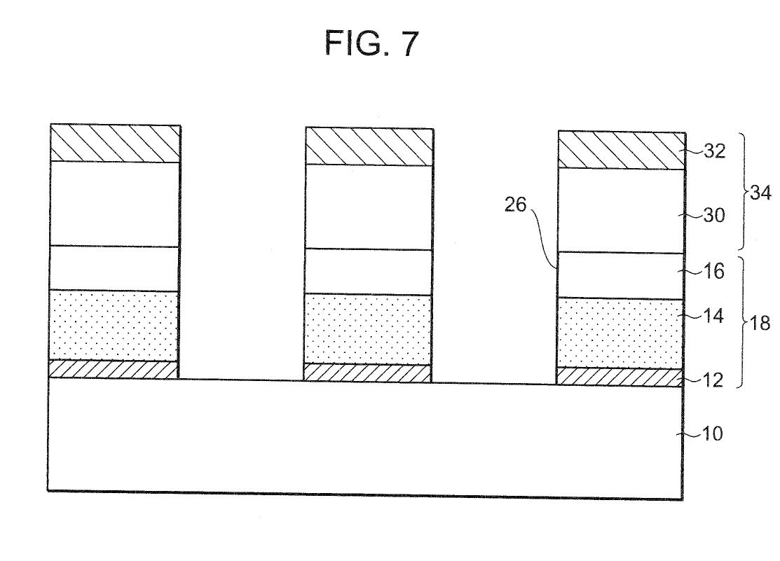

Following this, as shown in FIG. 7, etching of the insulating film 18 is performed using the multilayer resist film 34 as a mask, thereby forming the wiring grooves 26.

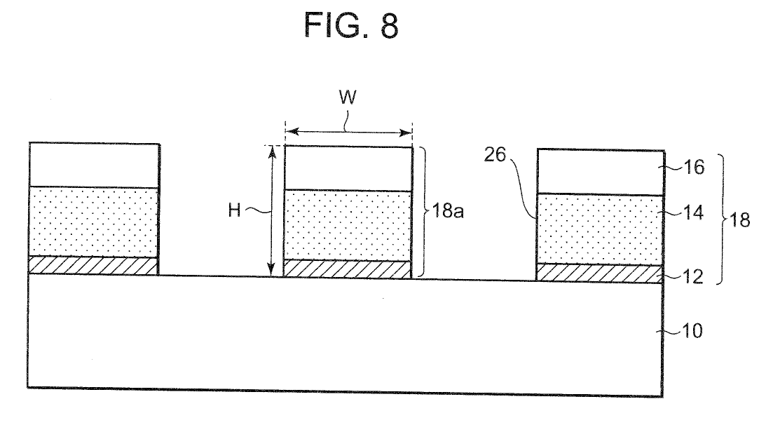

Next, as shown in FIG. 8, the multilayer resist film 34 is removed, thereby exposing an upper surface of the insulating film 18. When doing so, the aspect ratio Y (=H/W) of the insulating film 18a existing between the two wiring grooves 26 and the area X [nm²] of the side wall surfaces of the insulating film 18a are set so that the relation of “Y≦−2.9×10⁻⁷·X+9.49” is satisfied, so it becomes possible to prevent insulting film toppling over of the insulating film 18a.

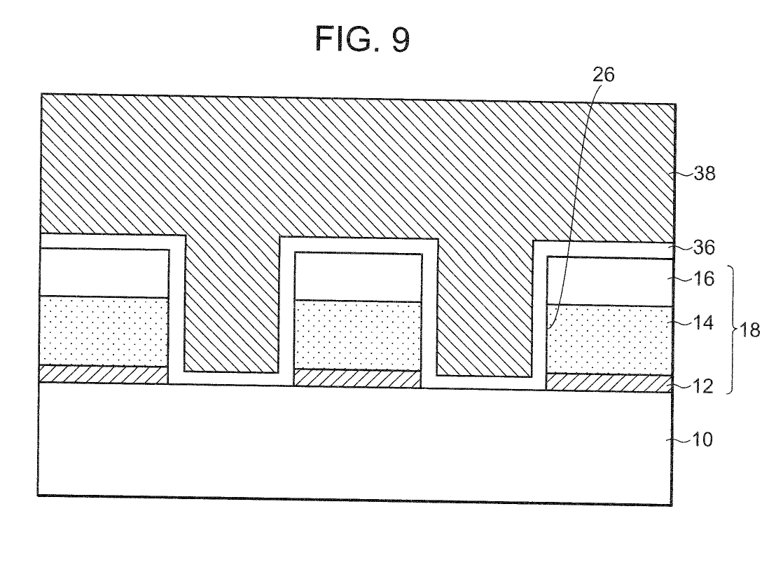

Next, as shown in FIG. 9, a barrier metal film 36 and a copper seed layer (not shown) are sequentially formed through sputtering and a copper film 38 is formed on the copper seed layer through plating so that the wiring grooves 26 are completely filled in.

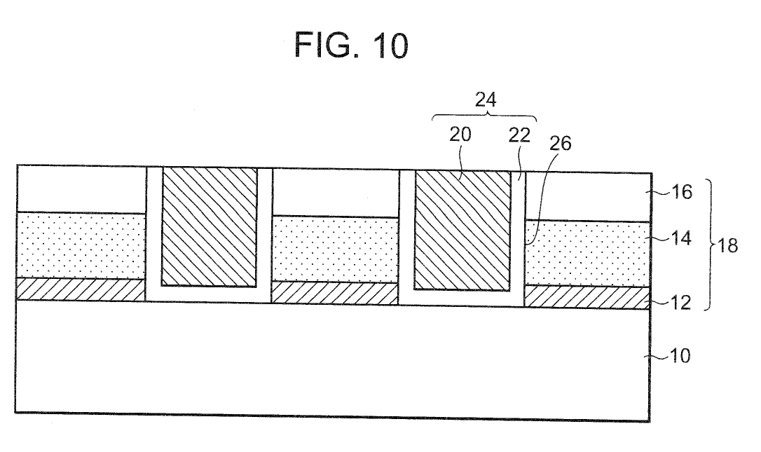

Next, as shown in FIG. 10, unnecessary portions of the barrier metal film 36 and the copper film 38 are removed through CMP, thereby forming the wirings 24 that each include the copper wiring 20 and the barrier metal 22.

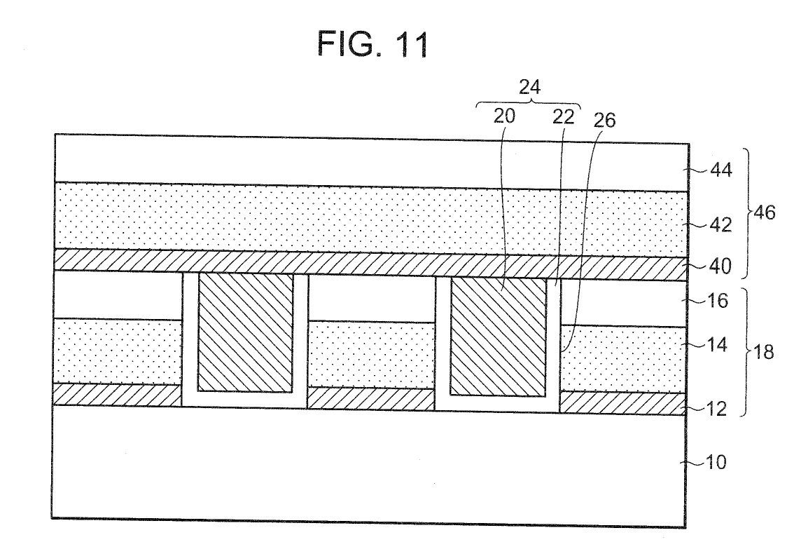

Following this, as shown in FIG. 11, an interlayer insulating film 46 is further formed on the wirings 24. For instance, like the insulating film 18, the interlayer insulating film 46 may have a construction including a cap film 44, a low-permittivity film 42, and an etching stopper film 40 in the stated order from the top. The cap film 44 is, for instance, an SiO2 film. The low-permittivity film 42 is, for instance, “Aurora” that is a porous film whose permittivity is around 2.5. The etching stopper film 40 is, for instance, an SiCN film. Note that FIG. 11 corresponds to a semiconductor device in which the interlayer insulating film 46 is provided on the semiconductor device 1 shown in FIG. 1.

Next, an effect of this embodiment will be described.

According to the semiconductor device of this embodiment, by limiting the side wall area X of the insulating film 18a in accordance with the aspect ratio Y of the insulting film 18a so that the aspect ratio Y of the insulting film 18a and the side wall area X [nm²] of the insulating film 18a are in the relation of “Y≦−2.9×10⁻⁷·X+9.49”, it becomes possible to suppress toppling over of the insulating film 18a, which makes it possible to prevent an increase in wiring resistance and a decrease in inter-wiring dielectric voltage resulting from the insulating film toppling over.

Also, it is preferable that this embodiment be applied to the insulating film 18a at a location at which the wirings are arranged with the minimum gap in-between in the semiconductor device. This is because the insulating film 18a at the location, at which the wirings are arranged with the minimum gap in-between in the semiconductor device, has a small width W and a large aspect ratio Y, so the insulating film toppling over tends to occur.

It should be noted here that in the explanation of this embodiment, copper has been described as an example of a material of the wirings 20 but the present invention is not limited thereto and a metal whose main component is copper and in which an impurity is added to the copper, may be used instead. Also, “Aurora” that is a porous film, whose permittivity is around 2.5, has been described as an example of the low-permittivity film 14 included in the insulating film 18, but the present invention is not limited thereto. A low-permittivity film whose permittivity is 3.5 or less may be used instead. This is because the low-permittivity film whose permittivity is 3.5 or less is generally low in film density and is low in mechanical strength as an insulating film as compared with an SiO2 film whose permittivity is about 4, so the insulating film toppling over tends to occur in a like manner.

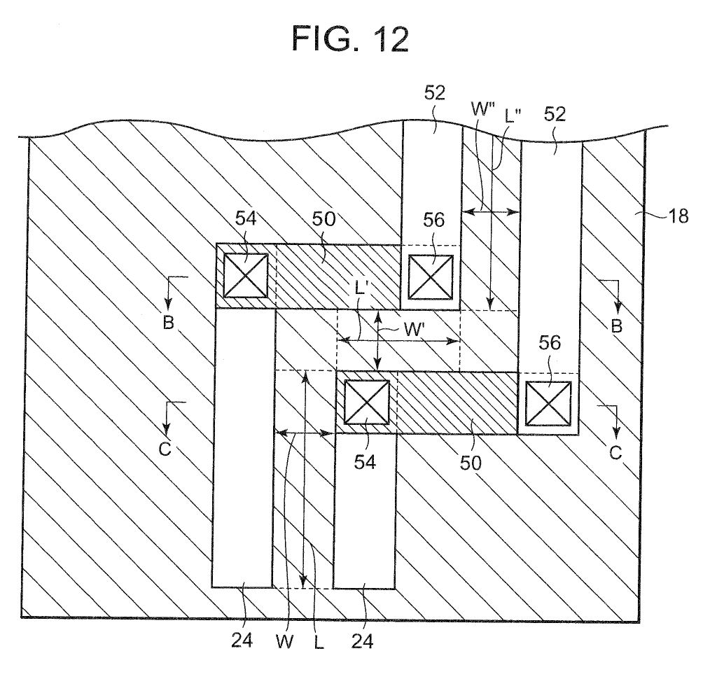

Further, in FIG. 2, the two wirings 24 that the insulating film 18a contacts are provided to have the same length but, as shown in FIG. 12, the two wirings 24 that the insulating film 18a contacts are not limited to the same length. In this case, as shown in FIG. 12, the length L of the insulating film 18a is defined by a length of a shorter wiring 24 (wiring on the right side in FIG. 12).

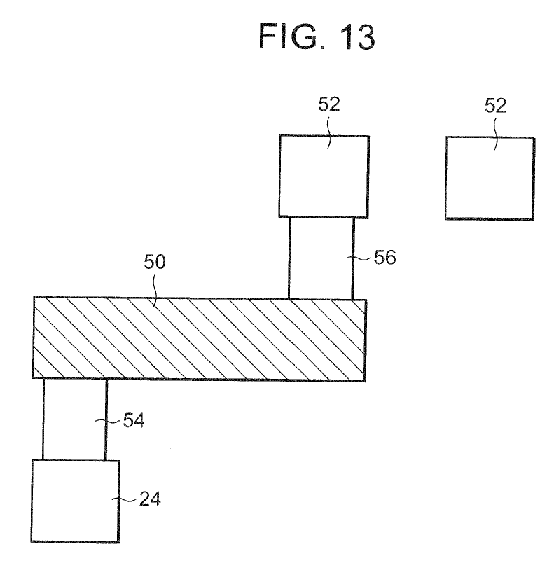

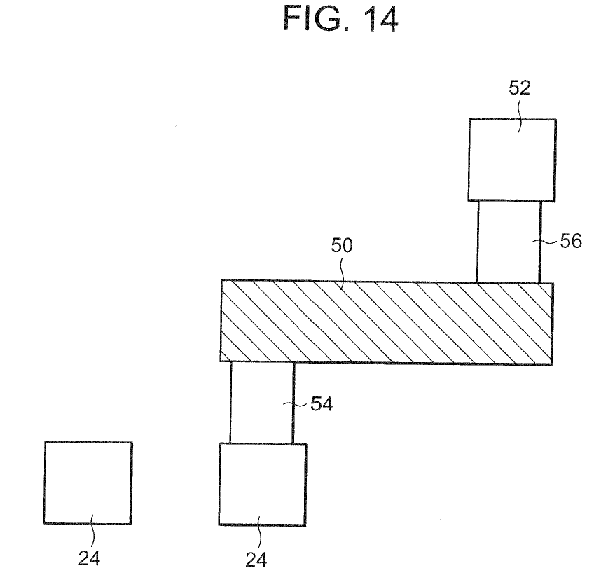

Still further, when wirings 50 in a wiring layer immediately upper than the wirings 24 are considered, a length L′ of the insulating film 18a is defined by a distance in which the adjacent wirings oppose each other (see FIG. 12). Also, when wirings 52 in a wiring layer next immediately upper than the wirings 24 are considered, a length L″ of the insulating film 18a is also defined by a distance, in which the adjacent wirings oppose each other, in a like manner (see FIG. 12). Note that the wirings 24 and the wirings 50 shown in FIG. 12 are electrically connected to each other through vias 54 as shown in FIG. 13 that is a B-B cross-sectional view of FIG. 12 and FIG. 14 that is a C-C cross-sectional view of FIG. 12. Also, the wirings 50 and the wirings 52 shown in FIG. 12 are electrically connected to each other through vias 56 as shown in FIG. 13 that is the B-B cross-sectional view of FIG. 12 and FIG. 14 that is the C-C cross-sectional view of FIG. 12. In FIGS. 13 and 14, the interlayer insulating film and the inter-wiring insulating film are omitted.

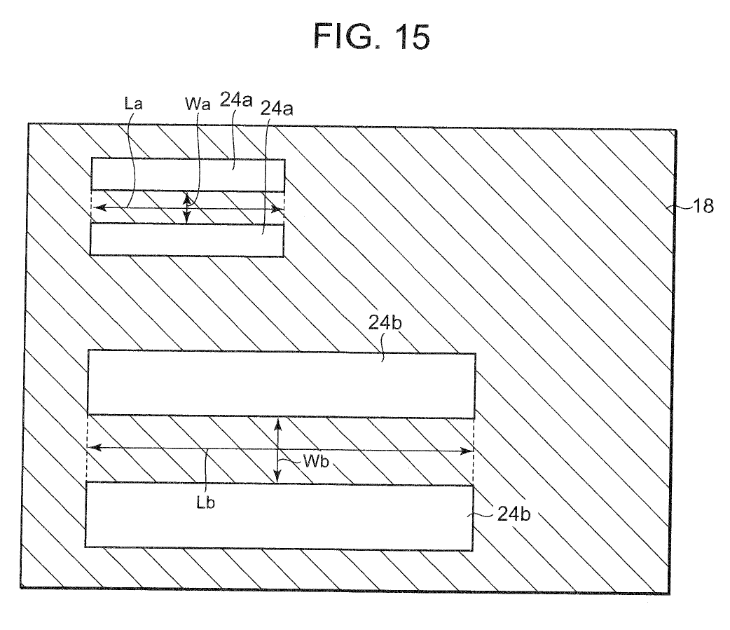

Also, in FIG. 15, an example is shown in which in the same wiring layer of the semiconductor device to which the present invention is applied, wirings 24a provided parallel to each other with the minimum wiring gap Wa in-between and wirings 24b provided parallel to each other with a wiring gap Wb wider than the minimum wiring gap in-between are arranged. It can be understood that the aspect ratio Y of the insulating film 18a and the side wall area X of the insulating film 18a satisfy the predetermined relation, so lengths La of the wirings 24a provided parallel to each other with the minimum wiring gap Wa in-between become shorter than lengths Lb of the wirings 24b provided parallel to each other with the wiring gap Wb wider than the minimum wiring gap in-between.

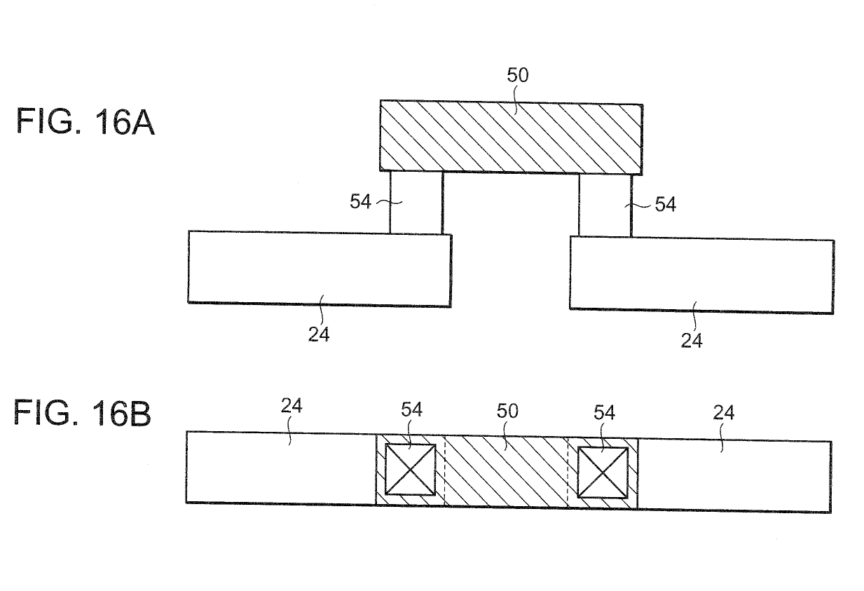

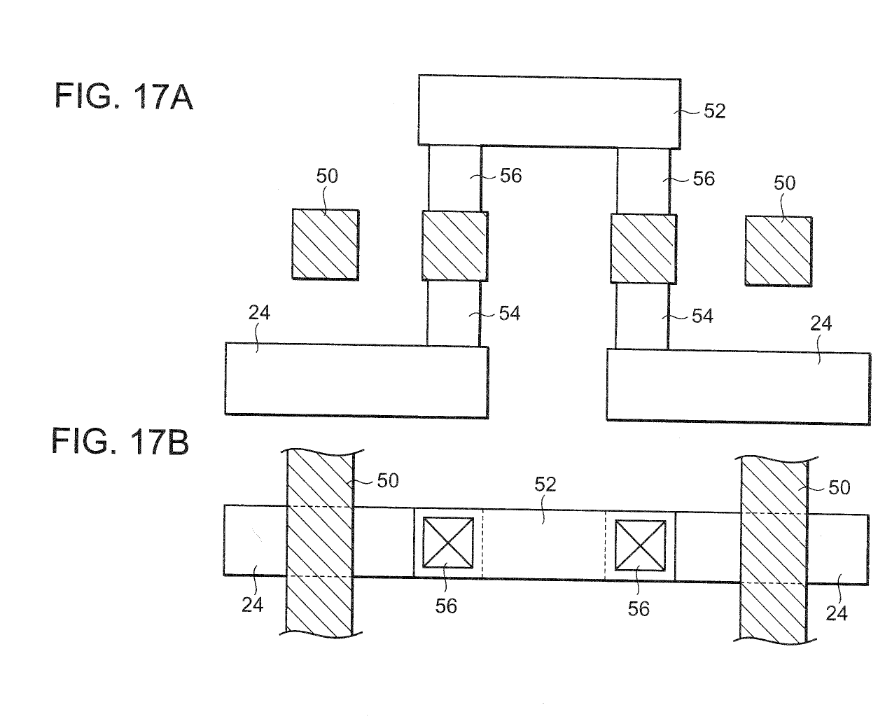

Further, connections among multiple wirings, whose wiring lengths are limited as a result of the application of the present invention, will be described with reference to FIGS. 16A, 16B, 17A, and 17B. FIGS. 16A and 16B each show a case where running directions of wirings are not determined depending on which of wiring layers the wirings are formed in, and FIGS. 17A and 17B each show a case where running directions of wirings are determined depending on which of wiring layers the wirings are formed in. FIG. 16A is a cross-sectional view and FIG. 16B is a top view of FIG. 16A. In a like manner, FIG. 17A is a cross-sectional view and FIG. 17B is a top view of FIG. 17A. In FIGS. 16A, 16B, 17A, and 17B, the interlayer insulating film and the inter-wiring insulating film are omitted.

When running directions of wirings are not determined depending on which of wiring layers the wirings are formed in, as shown in FIGS. 16A and 16B, two wirings 24, whose wiring lengths are limited, (the two wirings 24 are separated from each other by a not-shown inter-wiring insulating film) are connected to each other through vias 54 by a wiring 50 in an immediately upper wiring layer. With this construction, by connecting a desired number of wirings 24 to each other, it becomes possible to establish a connection between two points apart from each other by a desired distance with the wirings 24. Note that a construction is also possible in which the two wirings 24, whose wiring lengths are limited, are connected to each other using a wiring in an immediately lower wiring layer.

When running directions of wirings are determined depending on which of wiring layers the wirings are formed in, in other words, when a running direction of wirings in a certain wiring layer and a running direction of wirings in a wiring layer immediately upper than the certain wiring layer are determined to intersect at right angles, as shown in FIGS. 17A and 17B, two wirings 24, whose wiring lengths are limited, (the two wirings 24 are separated from each other by a not-shown inter-wiring insulating film) are connected to each other through vias 54, wirings 50 in an immediately upper wiring layer, and vias 56 by a wiring 52 in a next immediately upper wiring layer. With this construction, even when the running direction of the wirings in the certain wiring layer and the running direction of the wirings in the wiring layer immediately upper than the certain wiring layer are determined to intersect at right angles, by connecting a desired number of wirings 24 to each other, it becomes possible to establish a connection between two points apart from each other by a desired distance with the wirings 24. Note that a construction is also possible in which the two wirings 24, whose wiring lengths are limited, are connected to each other using a wiring in a next immediately lower wiring layer.

Although the present invention has been described above in connection with several preferred embodiments thereof, it is apparent that the present invention is not limited to above embodiments, but may be modified and changed without departing from the scope and spirit of the invention.

What is claimed is:

1. A semiconductor device, comprising:
a semiconductor substrate;
a first wiring provided over the semiconductor substrate and extending in a first direction;
a second wiring provided over the semiconductor substrate and extending in the first direction; and
an insulating film provided between the first wiring and the second wiring,
wherein an aspect ratio Y of the insulating film defined by a value obtained by dividing a height H of the insulating film by a width W of the insulating film along a direction vertical to the first direction and a side wall area X [nm²] of the insulating film in a portion contacting the first wiring and the second wiring have the following relation:
Y≦−2.9×10⁻⁷·X+9.49.

2. The semiconductor device according to claim 1, wherein the first wiring and the second wiring are adjacent to each other with a minimum gap in-between in the semiconductor device.

3. The semiconductor device according to claim 1, wherein the first wiring and the second wiring each comprise copper as a main component.

4. The semiconductor device according to claim 1, wherein the first wiring and the second wiring each comprise damascene structure wirings.

5. The semiconductor device according to claim 1, wherein the insulating film comprises:
a low-permittivity film;
a first insulating film provided in a layer upper than a low-permittivity film and having a higher permittivity than the low-permittivity film; and
a second insulating film provided a layer lower than the low-permittivity film and having a higher permittivity than the low-permittivity film.

6. The semiconductor device according to claim 5, wherein the low-permittivity film comprises a porous film.

7. The semiconductor device according to claim 1, further comprising a barrier metal provided on side walls and bottom surfaces of the first wiring and the second wiring.

8. A semiconductor device, comprising:
a first wiring and a second wiring running in parallel to each other with a predetermined gap therebetween; and
an insulating film interposed between the first wiring and the second wiring,
wherein when the predetermined gap is referred to as “W [nm] ”, a height of the first wiring is referred to as “H [nm] ” and a length of a portion of the first wiring facing the second wiring, is referred to as “L [nm] ”, the following relation is satisfied:
W/H≦−2.9×10⁻⁷×(L×H)+9.49.

9. The semiconductor device according to claim 8, further comprising a third wiring provided as an extension of the first wiring and being separated from the first wiring by an insulating film,
wherein the first wiring and the third wiring are electrically connected to each other through a fourth wiring provided in a wiring layer immediately upper than the first wiring and the third wiring.

10. The semiconductor device according to claim 9, wherein:
the first wiring and the fourth wiring are electrically connected to each other by a first via; and
the third wiring and the fourth wiring are electrically connected to each other by a second via provided in a via layer where the first via is provided.

11. The semiconductor device according to claim 8, further comprising a third wiring provided as an extension of the first wiring and being separated from the first wiring by an insulating film,
wherein the first wiring and the third wiring are electrically connected to each other through a fifth wiring provided in a wiring layer next immediately upper than the first wiring and the third wiring.

12. The semiconductor device according to claim 11, wherein:
the first wiring and the fifth wiring are electrically connected to each other by a first via, one of fourth wirings provided in a wiring layer immediately upper than the first wiring and the third wiring, and a second via; and
the third wiring and the fifth wiring are electrically connected to each other by a third via provided in a via layer where the first via is provided, another of the fourth wirings provided in the wiring layer immediately upper than the first wiring and the third wiring, and a fourth via provided in a via layer where the second via is provided.
